(19) United States
(12) Patent Application Publication
(10) Pub. No.: US 2025/0079272 A1
(43) Pub. Date: Mar. 6, 2025

(54) SEMICONDUCTOR DEVICE AND MANUFACTURING METHOD

(71) Applicant: FUJI ELECTRIC CO., LTD., Kawasaki-shi (JP)

(72) Inventor: Yuta SHIBASAKI, Matsumoto-city (JP)

(73) Assignee: FUJI ELECTRIC CO., LTD., Kawasaki-shi (JP)

(21) Appl. No.: 18/753,971

(22) Filed: Jun. 25, 2024

(30) Foreign Application Priority Data
Aug. 28, 2023 (JP) 2023-137672

(51) Int. Cl. H01L 23/495; H01L 21/48

(52) U.S. Cl. CPC H01L 23/49551; H01L 21/4842

(57) ABSTRACT

A semiconductor device, including a wiring member having a coil portion. The coil portion includes: a plurality of first slits and a plurality of second slits arranged alternately in a first direction, each first slit extending from a first side of the wiring member in a second direction, and each second slit extending from a second side of the wiring member in a direction opposite to the second direction, a plurality of first inter-slit regions each between one of the first slits and one of the second slits adjacent thereto in the first direction, and a plurality of second inter-slit regions each between one of the second slits and one of the first slits adjacent thereto in the first direction. The first and second inter-slit regions have first peak portions and second peak portions at center portions thereof, on opposite sides of a principal surface of the wiring member.

### CROSS-REFERENCE TO RELATED APPLICATION

This application is based upon and claims the benefit of priority of the prior Japanese Patent Application No. 2023-137672, filed on Aug. 28, 2023, the entire contents of which are incorporated herein by reference.

### BACKGROUND OF THE INVENTION

### 1. Field of the Invention

The embodiment discussed herein relates to a semiconductor device and a manufacturing method.

### 2. Background of the Related Art

For example, various kinds of electronic components such as a semiconductor chip that performs a switching operation and a control circuit that controls the switching operation of the semiconductor chip are mounted in a semiconductor device.

As related a art, static electricity protective circuit has been proposed, which is formed of an inductor having one end connected to a signal terminal and a Schottky barrier diode having a cathode connected to the other end of the inductor and an anode connected to the ground (see, for example, Japanese Laid-open Patent Publication No. 2005-117000).

Further, an oscillation circuit board has been proposed, in which a trimming portion for oscillation frequency adjustment is formed in a coil portion that forms an oscillation circuit in a conductive pattern formed on an insulating substrate, a groove portion is formed in the trimming portion, and a slit is formed inside the trimming portion (see, for example, Japanese Laid-open Patent Publication No. H09-270570).

Still further, a semiconductor device has been proposed, in which a conductive member is connected to a second surface of a cooling member, and a high-potential terminal part and a low-potential terminal part are selectively connected to a first surface of the cooling member and the conductive member, respectively (see, for example, Japanese Laid-open Patent Publication No. 2017-50336).

Still further, an electro-static discharge (ESD) protection device has been proposed, which includes a semiconductor substrate having first and second input/output electrodes electrically connected to an ESD protection circuit for a high-frequency line and a rewiring layer having first and second terminal electrodes connected to the input/output electrodes (see, for example, Japanese Laid-open Patent Publication No. 2014-33207).

Still further, a semiconductor device has been proposed, in which an electrostatic protection circuit is formed on a semiconductor chip different from a main semiconductor chip, an electrostatic protection chip is mounted on one principal surface of a lead frame on which the main semiconductor chip is mounted, and the bonding pad of the main semiconductor chip and the external pin of the lead frame are conductively connected with a wiring member via the electro-static protection chip (see, for example, Japanese Laid-open Patent Publication No. H06-140564).

Still further, an antenna device has been proposed, which is formed by punching, from a plate body, a shape having bending portions that are sequentially connected to one another with connection portions and bending the bending portions by 90 degrees from the punched body (see, for example, Japanese Laid-open Patent Publication No. 2005-341091).

Still further, an inductor component has been proposed, in which a first conductor pattern and a second conductor pattern are formed in a helical shape via through-hole conductors so that an inductor is formed by the first conductor pattern, the second conductor pattern, and the through-hole conductors (see, for example, Japanese Laid-open Patent Publication No. 2017-220502).

### SUMMARY OF THE INVENTION

According to one aspect, there is provided a semiconductor device, including: an electronic component; and an external connection wiring part formed of a wiring member that is of a plate shape and has two ends opposite to each other, a direction from one end to the other end thereof being a first direction, the one end thereof being connected to the electronic component, the wiring member including: a coil portion extending in the first direction, and two plate portions that are flat, respectively provided closer to the one end than is the coil portion and closer to the other end than is the coil portion, wherein in a top view of the wiring member, the wiring member has a first side and a second side opposite to each other, a direction from the first side to the second side being a second direction that is orthogonal to the first direction; and the coil portion includes: a plurality of first slits extending from the first side of the wiring member in the second direction, a plurality of second slits extending from the second side of the wiring member in a direction that is opposite to the second direction and orthogonal to the first direction, the plurality of first slits and the plurality of second slits being arranged alternately, a plurality of first inter-slit regions, each between one of the first slits and one of the second slits adjacent thereto in the first direction, and having a first peak portion at a center portion thereof, and a plurality of second inter-slit regions, each between one of the second slits and one of the first slits adjacent thereto in the first direction, and having a second peak portion at a center portion thereof, the plurality of first peak portions and the plurality of second peak portions being on opposite sides of a principal surface of the wiring member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 illustrates a comparative example of a semiconductor module;

FIG. 2 is a plan view of a semiconductor module according to one embodiment;

FIG. 3 includes a plan view, front view, and side view of a coil portion;

FIG. 4 is a perspective view of the coil portion;

FIG. 5 illustrates a coil portion manufacturing process;

FIG. 6 illustrates example dies used for forming the coil portion;

FIG. 7 is a sectional view illustrating an example arrangement of the coil portion in a case;

FIG. 8 is a view for describing input and output of a signal via a TEMP terminal;

FIG. 9 represents a current value obtained when a surge is applied;

FIG. 10 includes a plan view, front view, and side view illustrating a modification example of the coil portion; and

FIG. 11 is a perspective view illustrating the modification example of the coil portion.

### DETAILED DESCRIPTION OF THE INVENTION

Hereinafter, an embodiment will be described with reference to the accompanying drawings. In the following description, the terms “front surface” and “top surface” refer to an X-Y plane facing up (in the +Z direction) in a semiconductor device illustrated in drawings. Similarly, the term “up” refers to an upward direction (the +Z direction) in the semiconductor device illustrated in the drawings. The terms “rear surface” and “bottom surface” refer to an X-Y plane facing down (in the −Z direction) in the semiconductor device illustrated in the drawings. Similarly, the term “down” refers to a downward direction (the −Z direction) in the semiconductor device illustrated in the drawings. The same directionality applies to other drawings, as appropriate. The terms “front surface,” “top surface,” “up,” “rear surface,” “bottom surface,” “down,” and “side surface” are used for convenience to describe relative positional relationships, and do not limit the technical ideas of the embodiment. For example, the terms “up” and “down” are not always related to the vertical directions to the ground. That is, the “up” and “down” directions are not limited to the gravity direction.

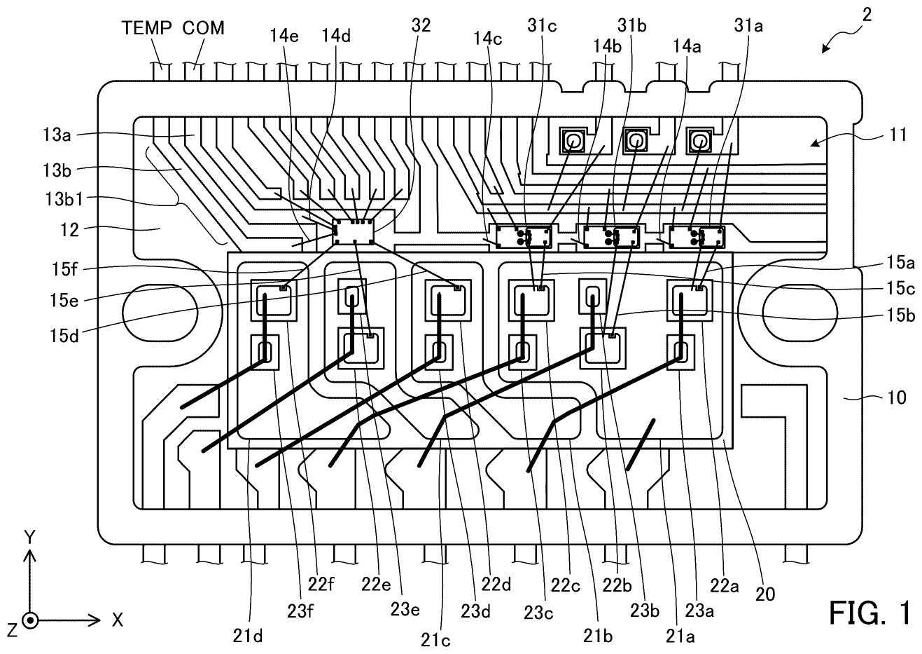

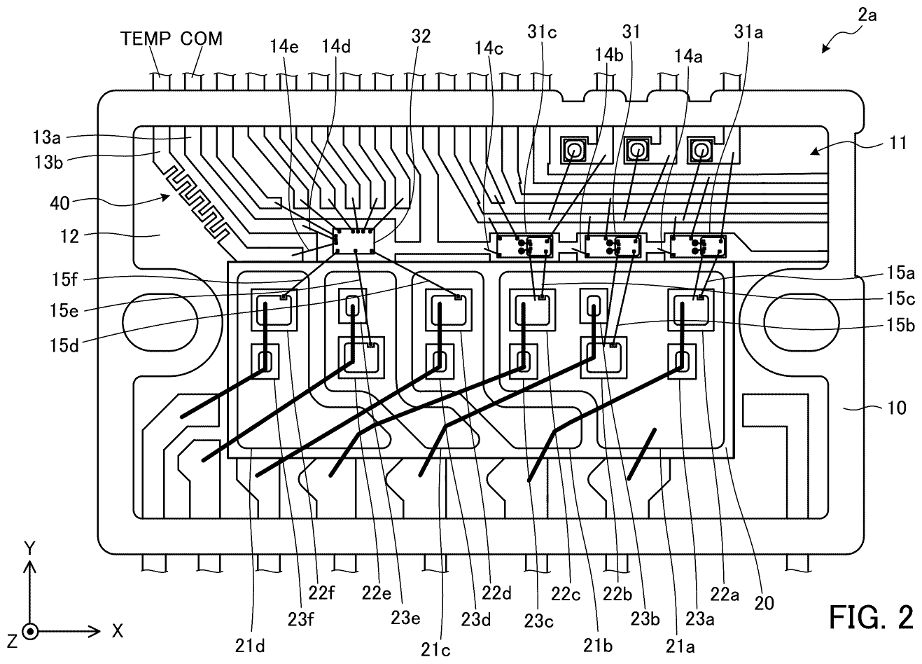

First, a comparative of example a semiconductor module included in a semiconductor device will be described with reference to FIG. 1. Then, a semiconductor module included in a semiconductor device according to one embodiment will be described with reference to FIG. 2.

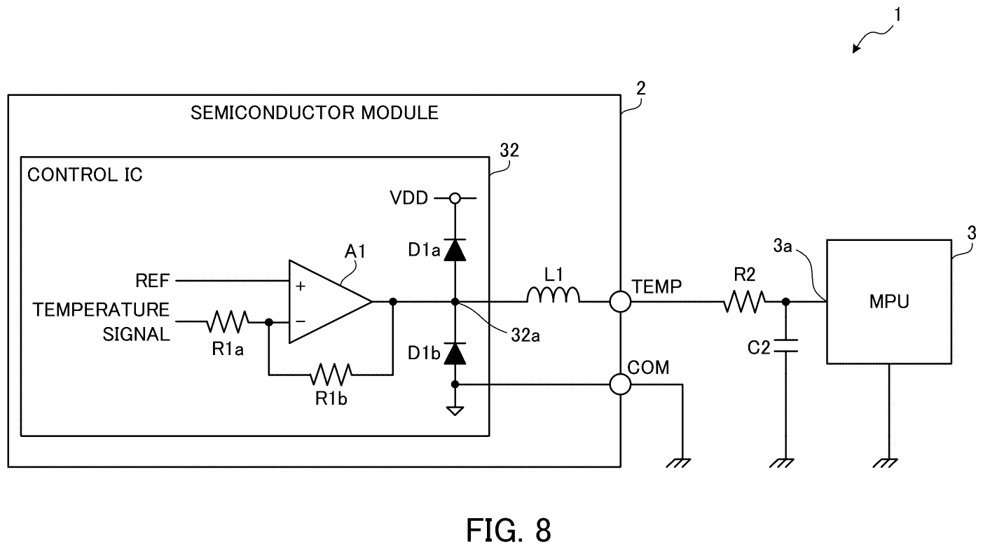

FIG. 1 illustrates a comparative example of a semiconductor module. FIG. 1 is a plan view of a semiconductor module 2 included in a semiconductor device 1 (see FIG. 8) as seen from above (as seen in the −Z direction).

The semiconductor module 2 is attached to the front surface of a cooling board, which is not illustrated. The semiconductor module 2 has a cuboid-shaped case 10. In plan view, the case 10 is surrounded on its periphery by side walls and has a housing region 11 for housing various components inside the side walls.

The housing region 11 is sealed with a sealing material, which is not illustrated. The sealing material may be a thermosetting resin. Examples of the thermosetting resin include an epoxy resin, a phenolic resin, a maleimide resin, and a polyester resin. The epoxy resin is preferable. In addition, a filler may be added to the sealing material. The filler is made of insulating ceramics with high thermal conductivity.

This case 10 is integrally formed with a plurality of lead frames, which will be described later, using a thermoplastic resin. Examples of the resin include a polyphenylene sulfide resin, a polybutylene terephthalate resin, a polybutylene succinate resin, a polyamide resin, and an acrylonitrile-butadiene-styrene resin.

An opening is formed at the bottom of the case 10. A heat dissipation plate, not illustrated, is provided on the rear surface side of the bottom of the case 10. The heat dissipation plate covers the opening of the case 10. An insulating board 20 is provided in the opening on the heat dissipation plate. Therefore, the front surface of the insulating board 20 is sealed with the sealing material. The insulating board 20 may be made of ceramics or an insulating resin. Examples of the ceramics include aluminum oxide, aluminum nitride, and silicon nitride. Examples of a board made of the insulating resin include a paper phenolic board, a paper epoxy board, a glass composite board, and a glass epoxy board.

Wiring plates 21a to 21d are formed on the front surface of the insulating board 20. The wiring plates 21a to 21d are made of a metal with high electrical conductivity. Examples of the metal include copper, aluminum, and an alloy containing at least one of these. In addition, the surfaces of the wiring plates 21a to 21d may be plated. Examples of the plating material used here include nickel, a nickel-phosphorus alloy, and a nickel-boron alloy. The plated wiring plates 21a to 21d exhibit improved corrosion resistance.

Semiconductor chips 22a to 22c and 23a to 23c are disposed on the front surface of the wiring plate 21a. Semiconductor chips 22d and 23d are disposed on the front surface of the wiring plate 21b. Semiconductor chips 22e and 23e are disposed on the front surface of the wiring plate 21c. Semiconductor chips 22f and 23f are disposed on the front surface of the wiring plate 21d.

Each semiconductor chip 22a to 22e includes a switching element. For example, the switching element is an insulated gate bipolar transistor (IGBT) or a power metal-oxide-semiconductor field-effect transistor (MOSFET). Each semiconductor chip 23a to 23e also includes a diode element. For example, the diode element may be a free-wheeling diode (FWD) such as a Schottky barrier diode (SBD) or a P-intrinsic-N(PiN) diode.

The case 10 has a bottom surface 12 in a region except for the aforementioned opening at the bottom thereof. The bottom surface 12 has a flat front surface. For example, the bottom surface 12 is located higher than the front surface of the insulating board 20. In addition, a plurality of lead frames including the lead frames 13a and 13b are provided on the front surface of the bottom surface 12. These plurality of lead frames are made of a material with high electrical conductivity. Examples of the material include copper, aluminum, and an alloy containing at least one of these. In addition, each lead frame may be plated with a material with high corrosion resistance.

One end of the lead frame 13a extends from inside the case 10 to the outside (in the +Y direction). The other end of the lead frame 13a that is continuous with the one end goes inside the case 10 and extends to the short side (on the +X side) of the case 10 along the long side of the insulating board 20. This lead frame 13a is connected to a common terminal (COM terminal). In addition, control integrated circuits (ICs) 31a to 31c and 32 are disposed adjacent to the long side of the insulating board 20 on the front surface of the lead frame 13a. The electrodes formed on the front surfaces of the control ICs 31a to 31c and 32 are connected to the lead frame 13a via bonding wires 14a to 14d, respectively.

One end of the lead frame 13b extends from inside the case 10 to the outside (in the +Y direction). The other end of the lead frame 13b that is continuous with the one end goes inside the case 10 and extends to the side of the insulating board 20 adjacent to the wiring plate 21d. This lead frame 13b is connected to a TEMP terminal. In addition, a temperature sensing electrode formed on the front surface of the control IC 32 and the lead frame 13b are connected to each other with a bonding wire 14e. The TEMP terminal is an output terminal to output a temperature sense signal. A voltage signal corresponding to the temperature of the control IC 32 is transferred to the TEMP terminal through the bonding wire 14e and lead frame 13b and is output from the TEMP terminal to the outside.

In the above-described semiconductor module 2, the semiconductor chips 22a and 23a and semiconductor chips 22d and 23d form an inverter circuit for one phase. The semiconductor chips 22a and 23a form the upper arm of a half-bridge circuit, and the semiconductor chips 22d and 23d form the lower arm of the half-bridge circuit. In addition, the semiconductor chips 22b and 23b and semiconductor chips 22e and 23e form an inverter circuit for one phase. The semiconductor chips 22b and 23b form the upper arm of a half-bridge circuit, and the semiconductor chips 22e and 23e form the lower arm of the half-bridge circuit. The semiconductor chips 22c and 23c and semiconductor chips 22f and 23f form an inverter circuit for one phase. The semiconductor chips 22c and 23c form the upper arm of a half-bridge circuit, and the semiconductor chips 22f and 23f form the lower arm of the half-bridge circuit.

The control electrode formed on the front surface of the control IC 31a and the gate electrode formed on the front surface of the semiconductor chip 22a are connected to each other with a bonding wire 15a. The control electrode formed on the front surface of the control IC 31b and the gate electrode formed on the front surface of the semiconductor chip 22b are connected to each other with a bonding wire 15b. The control electrode formed on the front surface of the control IC 31c and the gate electrode formed on the front surface of the semiconductor chip 22c are connected to each other with a bonding wire 15c. The control ICs 31a to 31c are gate driver ICs for the upper arms, and are designed to output gate control signals to the gate electrodes of the semiconductor chips 22a to 22c in order to control the switching operations of the semiconductor chips 22a to 22c, respectively.

The control electrode formed on the front surface of the control IC 32 is connected to the gate electrodes formed on the front surfaces of the semiconductor chips 22d to 22f with bonding wires 15d to 15f, respectively. The control IC 32 is a gate driver IC for the lower arms and is designed to output a gate control signal to the gate electrodes of the semiconductor chips 22d to 22f in order to control the switching operations of the semiconductor chips 22d to 22f, respectively.

For example, the semiconductor module 2 configured as above forms an intelligent power module (IPM) in which switching elements and control circuit are accommodated in one package.

In this connection, a combination of the semiconductor chip 22a including a switching element and the semiconductor chip 23a including a diode element may be implemented on one chip as a reverse conducting (RC)-IGBT. Similarly, a combination of the semiconductor chips 22b and 23b, a combination of the semiconductor chips 22c and 23c, a combination of the semiconductor chips 22d and 23d, a combination of the semiconductor chips 22e and 23e, and a combination of the semiconductor chips 22f and 23f may each be implemented as an RC-IGBT.

By the way, there is a possibility that the control ICs 31a to 31c and 32 in the semiconductor module 2 are damaged due to the effects of a high frequency surge coming in from the outside. One approach to prevent such damage, for example, is to provide a protection element device such as a Zener diode or a bypass capacitor between an external terminal and a control IC. This approach is expected to suppress an overvoltage caused by such a high frequency surge, but is insufficient to suppress an overcurrent. In the control ICs 31a to 31c and 32, a latch-up failure may occur due to an inrush current caused by a high-frequency surge flowing into the internal parasitic transistors. However, the above approach is not able to overcome this problem. In addition, an approach to add a protection element device or to increase the withstand voltages of the control ICs involves an increase in the chip sizes of the control ICs, which accordingly causes a problem of increasing the size of the semiconductor module 2.

FIG. 2 is a plan view of a semiconductor module according to the embodiment. The same reference numerals as used in FIG. 1 are given to corresponding components illustrated in FIG. 2.

A semiconductor module 2a according to the present embodiment differs from the comparative example of FIG. 1 in that the semiconductor module 2a includes a coil portion 40 in a region 13b1 (see FIG. 1) of the lead frame 13b. The lead frame 13b has a greater width in the region 13b1 than that of FIG. 1. The coil portion 40 is formed by performing a slitting process and a bending process in the region 13b1 of the lead frame 13b.

In the semiconductor module 2 of the comparative example, a temperature sense signal of the control IC 32 flows through the lead frame 13b in the form of voltage, and the voltage is output from the TEMP terminal. Since the signal line for the temperature sense signal is designed to output a voltage, the control IC 32 has characteristics of being vulnerable to a high-frequency overcurrent, compared with the other control ICs 31a to 31c. That is, if a large current is input from the outside to the TEMP terminal, a clamping voltage appears across a protection element in the control IC 32, which damages a part with low breakdown voltage.

To deal with this, in the semiconductor module 2a, the lead frame 13b (external connection wiring part) through which a temperature sense voltage signal flows is provided with the coil portion 40. When a high-frequency surge is applied from the TEMP terminal, the coil portion 40 delays a rise in current flowing therethrough, which results in lowering the peak of the current. Therefore, the current to be applied to the control IC 32 (electronic component) is suppressed, which reduces the possibility of damage to the control IC 32.

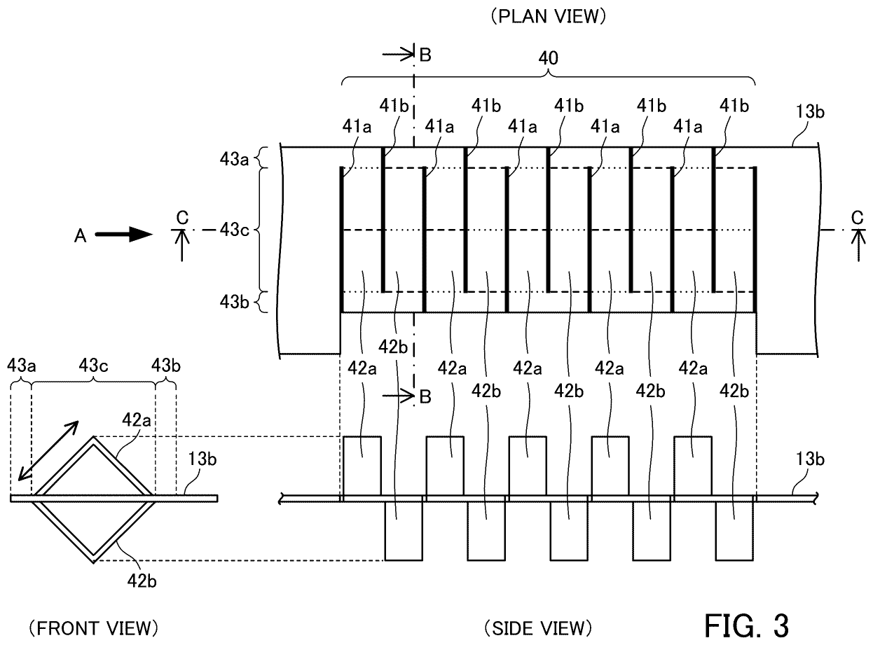

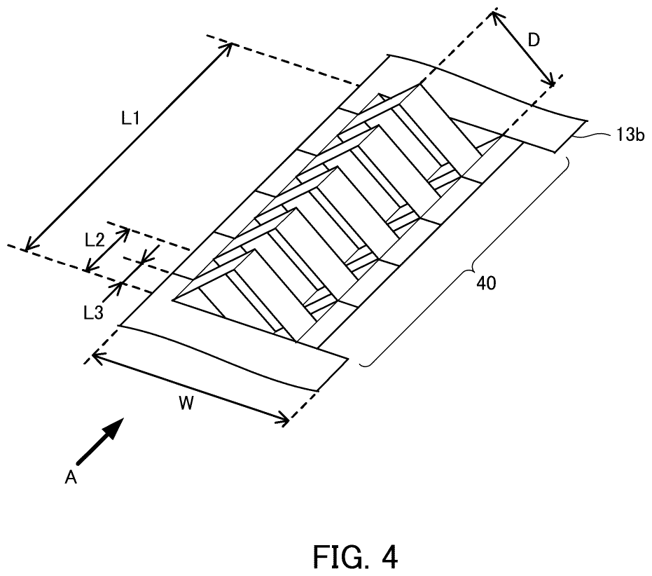

The following describes the structure of the coil portion with reference to FIGS. 3 and 4. FIG. 3 includes a plan view, front view, and side view of the coil portion. FIG. 4 is a perspective view of the coil portion. In this connection, FIG. 3 includes a plan view, a front view, and a side view, taking the side seen in the extending direction (direction of arrow A) of the lead frame 13b as the front side.

In the region for the coil portion 40 in the lead frame 13b, when viewed from the front (when viewed in the direction of arrow A (first direction)), a plurality of sets each including a slit 41a (first slit) extending from the right side (from the bottom in the plan view of FIG. 3) in a direction (second direction) orthogonal to the lead frame 13b and a slit 41b (second slit) extending from the left side (from the top in the plan view of FIG. 3) in a direction (direction opposite to the second direction) orthogonal to the lead frame 13b are provided such that the first slit 41a and second slit 41b are alternately arranged. That is, in the width direction of the lead frame 13b, the slit 41a reaches the right side, but does not reach the left side. The slit 41b, on the other hand, reaches the left side but does not reach the right side in the width direction of the lead frame 13b. In addition, adjacent slits are formed at regular intervals.

When viewed from the front, an inter-slit region 42a (first inter-slit region) between a slit 41a and its adjacent slit 41b is bent such that the center portion in the width direction of the inter-slit region 42a projects upward (in a third direction) with respect to the principal surface of the lead frame 13b to form a first peak portion. On the other hand, when viewed from the front, an inter-slit region 42b (second inter-slit region) between a slit 41b and its adjacent slit 41a is bent such that the center portion in the width direction of the inter-slit region 42b projects downward (in a direction opposite to the third direction) with respect to the principal surface of the lead frame 13b to form a second peak portion.

In this connection, the region for the coil portion 40 in the lead frame 13b includes, in the width direction, a side region 43a without the slits 41a, a side region 43b without the slits 41b, and the remaining central region 43c. The side region 43a and side region 43b are kept on the same plane as the principal surface of the lead frame 13b, and only the central region 43c has projections projecting upward and downward. In the plan view of FIG. 3, broken lines are fold lines to form upward or diagonally upward projections with respect to the principal surface of the lead frame 13b, whereas dotted lines are fold lines to form downward or diagonally downward projections with respect to the principal surface of the lead frame 13b.

Therefore, the inter-slit region 42a projecting upward and the inter-slit region 42b projecting downward with respect to the principal surface of the lead frame 13b appear alternately, and adjacent inter-slit regions are connected to each other with the side region 43a or side region 43b. As a result, a coil having a rectangular (rhombus) cross-section is formed by the inter-slit regions 42a projecting upward and the inter-slit regions 42b projecting downward.

In this connection, the slits 41a and 41b are formed to have a fixed width. This prevents adjacent inter-slit regions with a slit therebetween from contacting each other. More specifically, the inter-slit region 42a and the inter-slit region 42b located adjacent to the inter-slit region 42a in the direction of arrow A are separate by the width of the slit 41b from each other in the side region 43a. Similarly, the inter-slit region 42b and the inter-slit region 42a located adjacent to the inter-slit region 42b in the direction of arrow A are separate by the width of the slit 41a from each other in the side region 43b.

The coil configured as above increases the inductance components of the lead frame 13b. Therefore, when a high-frequency surge is applied from the TEMP terminal, a rise in current flowing to the control IC 32 through the lead frame 13b is delayed, and the peak of the current is accordingly lowered. This results in suppressing the current to be applied to the control IC 32, thereby reducing the possibility of damage to the control IC 32.

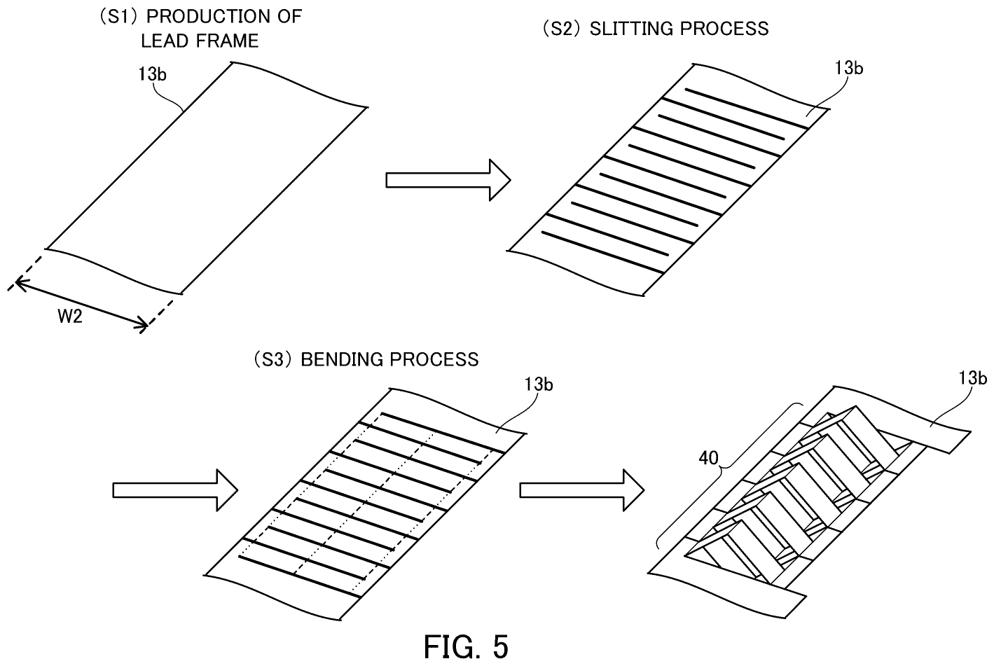

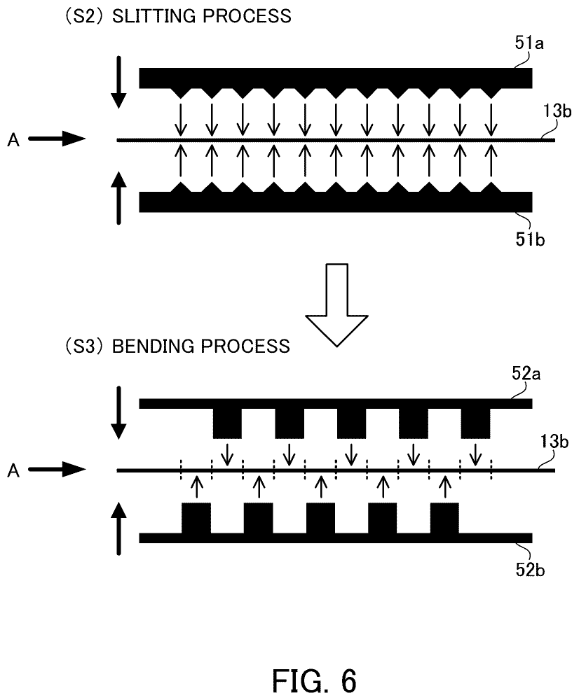

The following describes a method of manufacturing the coil portion 40 with reference to FIGS. 5 and 6.

FIG. 5 illustrates a coil portion manufacturing process. FIG. 6 illustrates example dies used for forming the coil portion.

First, a conductive plate with a thickness of 0.4 mm is pressed using a die to cut out the lead frame 13b (step S1). At this time, a plurality of frames including the lead frames 13a and 13b are actually formed in the state of being connected to each other with a tie bar. In addition, the width W of a region where the coil portion 40 is to be formed in the lead frame 13b is wider than the width of the region 13b1 of the comparative example illustrated in FIG. 1. For example, the width W is increased from 2 mm to 6 mm. Note, however, that the region other than the region where the coil portion 40 is to be formed in the lead frame 13b may have the same width of 2 mm as in the comparative example.

Then, the slitting process is performed in the region for the coil portion 40 in the lead frame 13b, to form the slits 41a and 41b (step S2). For example, a pair of dies 51a and 51b as illustrated in FIG. 6 are used. The facing surfaces of the dies 51a and 51b are provided with blades corresponding to the shapes of the slits 41a and 41b. The slits 41a and 41b are formed by sandwiching the lead frame 13b from the top and the bottom with the dies 51a and 51b.

After that, the bending process is performed on the inter-slit regions 42a and 42b (step S3). For example, a pair of dies 52a and 52b as illustrated in FIG. 6 are used. The upper die 52a has projections projecting downward at positions corresponding to the inter-slit regions 42b, and the lower die 52b has projections projecting upward at positions corresponding to the inter-slit regions 42a. Then, the lead frame 13b with the slits are sandwiched from the top and the bottom with the dies 52a and 52b and are pressed.

Each projection of the die 52a has an isosceles triangle with its vertex pointing upward in a cross s section when viewed from the front of the projection (when viewed in the direction of arrow A). Each projection of the die 52b has an isosceles triangle with its vertex pointing downward in a cross section when viewed from the front of the projection. Therefore, by the pressing, the projections of the die 52a bend the inter-slit regions 42b downward, and the projections of the die 52b bend the inter-slit regions 42a upward. As a result, in the central region 43c of the coil portion 40 in the lead frame 13b, adjacent inter-slit regions are bent to form a bellows shape so that the inter-slit regions project in opposite directions alternately with respect to the principal surface of the lead frame 13b, thereby forming a coil.

As described above, a simple method of slitting and bending flat plate-shaped conductive plate may be employed to form a coil. Therefore, a circuit component for overcurrent suppression is added at a low cost. In addition, the circuit component for overcurrent suppression is provided inside the semiconductor module 2a, which eliminates the need to ensure a space for disposing such a circuit component outside the semiconductor module 2a and thus prevents an increase in the size of the semiconductor device 1 as a whole. Furthermore, to form the coil, an existing lead frame needs be modified so that a region for forming the coil has a larger width only, which prevents an increase in the size of the semiconductor module 2a. A free space in the semiconductor module 2a may be used for forming the coil, which makes it possible to form the coil without the need of increasing the size of the semiconductor module 2a, in order to reduce the possibility of damage to the control IC 32.

In this connection, the coil in the coil portion 40 may be formed to have a winding direction opposite to that of the example described earlier with reference to FIGS. 3 to 6. The winding direction of the coil may be changed by changing the order of forming the slits 41a extending from the right side (from the bottom in the plan view of FIG. 3) of the lead frame 13b and the slits 41b extending from the left side of the lead frame 13b with respect to the direction of arrow A. More specifically, FIGS. 3 to 6 illustrate an example in which the slits 41a are first formed and then the slits 41b are formed so that the slits 41a and 41b are arranged in this order in the direction of arrow A. However, the winding direction of the coil may be changed to an opposite direction by forming the slits 41b first and then the slits 41a so that the slits 41b and 41a are arranged in this order in the direction of arrow A.

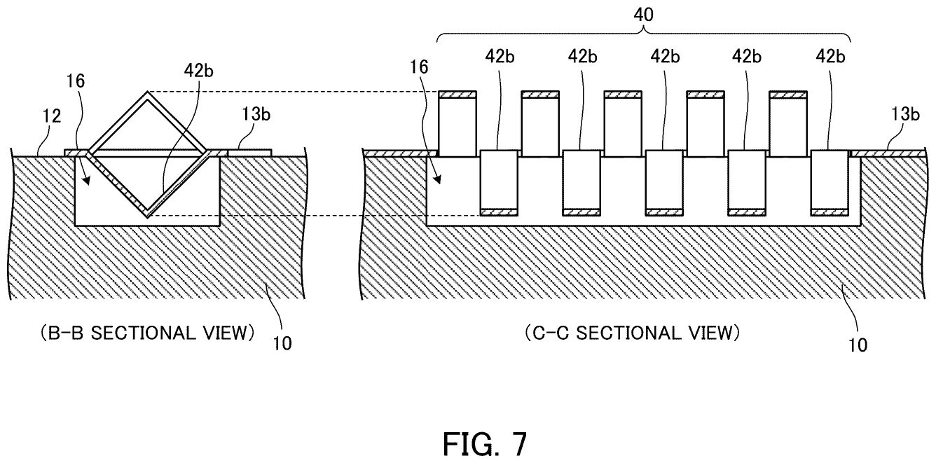

FIG. 7 includes sectional views illustrating an example arrangement of a coil portion in a case. FIG. 7 includes a sectional view (B-B sectional view) taken along a dash-dotted line B-B of FIG. 3 and a sectional view (C-C sectional view) taken along a dash-dotted line C-c.

The lead frame 13b is arranged on the front surface (flat surface) of the bottom surface 12 of the case 10. The inter-slit regions 42b of the coil portion 40 project downward from the principal surface of the lead frame 13b. For this reason, the case 10 has a recess 16 whose size and shape are enough to accommodate at least the inter-slit regions 42b, in a region below the coil portion 40. Referring to the example of FIG. 7, the recess 16 has vertical sides in the B-B sectional view. Alternatively, the recess 16 may have inclined sides to match the inclination of the inter-slit regions 42b. This recess 16 is formed in the case 10, and the lead frame 13b is arranged such that the inter-slit regions 42b are placed in the recess 16. This approach makes it possible to arrange the lead frame 13b having the coil portion 40 formed therein, on the front surface of the bottom surface 12 having the same height as in the comparative example of FIG. 1, without deforming the three-dimensional shape of the coil portion 40.

FIG. 8 is a view for describing input and output of a signal via a TEMP terminal.

As described earlier, the TEMP terminal is an external output terminal to output a temperature sense signal of the control IC 32 in the form of voltage to the outside. To output such a voltage signal, the control IC 32 has a circuit configuration as illustrated in FIG. 8, for example.

The control IC 32 includes an operational amplifier Al. A constant reference voltage REF is input to the non-inverting input terminal of the operational amplifier Al. A temperature signal corresponding to a temperature detected by the temperature sensor, not illustrated, provided in the control IC 32 is input to the inverting input terminal of the operational amplifier Al via a resistor R1a. A resistor R1b is connected between the output terminal and inverting input terminal of the operational amplifier Al to form a negative feedback circuit. With this configuration, a differential amplifier is formed, which amplifies the difference between the reference voltage REF and the voltage of the temperature signal with an amplification factor corresponding to the resistance ratio of the resistor R1a and the resistor R1b, so that a voltage corresponding to the temperature of the control IC 32 is output from the operational amplifier Al.

In addition, the anode of a diode D1a and the cathode of a diode Db are connected to the output terminal of the operational amplifier Al. A power supply voltage VDD is applied to the cathode of the diode D1a, and the anode of the diode D1b is connected to the COMP terminal and the ground. Furthermore, a connecting point 32a between the anode of the diode D1a and the cathode of the diode D1b is connected to the TEMP terminal via the lead frame 13b.

In addition, the semiconductor device 1 includes a micro processing unit (MPU) 3 for control. The MPU 3 has an input terminal 3a, and a temperature sense signal output from the TEMP terminal is input to the input terminal 3a through a resistor R2. One end of a capacitor C2 is connected between the resistor R2 and the input terminal 3a, and the other end of the capacitor C2 is connected to the ground. The resistor R2 and capacitor C2 limit an inrush current.

The diodes D1a and D1b are protection circuits that protect the control IC 32 against a surge input from the TEMP terminal. However, when a large current due to a high-frequency surge is input from the TEMP terminal, a clamping voltage appears across the diode D1b. The gate of the transistor included in the operational amplifier Al has a low breakdown voltage and may be damaged due to the clamping voltage.

To deal this, the present embodiment provides a coil L1 in the path between the connecting point 32a and the TEMP terminal. The coil L1 corresponds to the above-described coil portion 40. When a high-frequency surge is applied to the TEMP terminal from the outside, a rise in an input current is delayed by the inductance of the coil L1, which lowers the peak of the current to be applied to the operational amplifier Al. Therefore, it is possible to reduce the possibility of damage to the operational amplifier Al. As a result, the possibility of damage to the control IC 32 due to a high-frequency surge is reduced, and the reliability of the semiconductor device 1 is improved accordingly.

The following describes an example design of a coil.

For example, in type 2 of ESD test standards in joint electron device engineering council (JEDEC), an inrush current of 1.33 A/2 nsec is expected when 2000 V is applied. Therefore, suppose the case of applying an inrush current of 1.33 A/2 nsec to the TEMP terminal from a human body model (HBM) power supply having an internal resistance of 1.5 kΩ and an internal capacity of 100 pF. With the control IC 32 having a latch-up resistance of 500 ρA, a composite impedance is designed such that an input current flowing to the control IC 32 does not exceed 500 ρA when the above inrush current is applied. In the case where the control IC 32 has an internal resistance of 300Ω, an inductance of 950 nH or greater is needed to satisfy Z=(R₂+ω₂L₂)^{1/2}=4 MΩ.

As illustrated in FIG. 4, the length of the coil portion 40 is taken as L1, the length of one turn (=a distance of two slits) of a coil measured in the length direction of the coil portion 40 is taken as L2, and the width of the coil is taken as L3. In addition, the width of the lead frame 13b in which the coil portion 40 is formed is taken as W, and the length of one side of the square cross section of the coil is taken as D. This length D is considered as the diameter of the coil.

Consider, as an example, the case of forming a coil with the number of turns n=20, using W=6 mm, D=2 mm, and L1=15 mm. In this case, L2 becomes equal to 0.75 mm. Considering the width of slits, L3 is set to 0.3 mm. The inductance is calculated as K×μ₀×π×(D/2)²×n²/L1. K (Nagaoka coefficient) is 0.92, and po denotes a vacuum permeability. Considering that the inductance of the lead frame 13b is 10 nH before the formation of the coil, the inductance of 970 nH is ensured by forming the above-dimensioned coil portion 40.

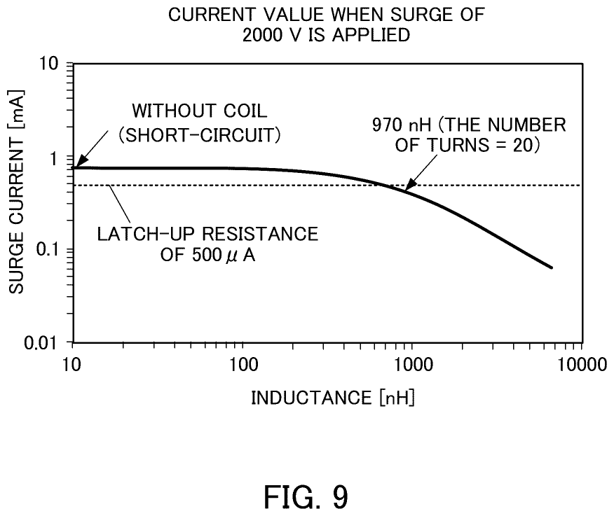

FIG. 9 represents a current value obtained when a surge is applied. FIG. 9 represents the relation between an inductance value and a surge current value when a surge of 2000 V is applied. In the case where the coil portion 40 is not formed (comparative example of FIG. 1), the surge current exceeds the latch-up resistance of 500 μA of the control IC 32. However, by forming the coil portion 40 with the number of turns n=20 as described above to ensure an inductance of 970 nH, it becomes possible to reduce the surge current to be less than the latch-up resistance.

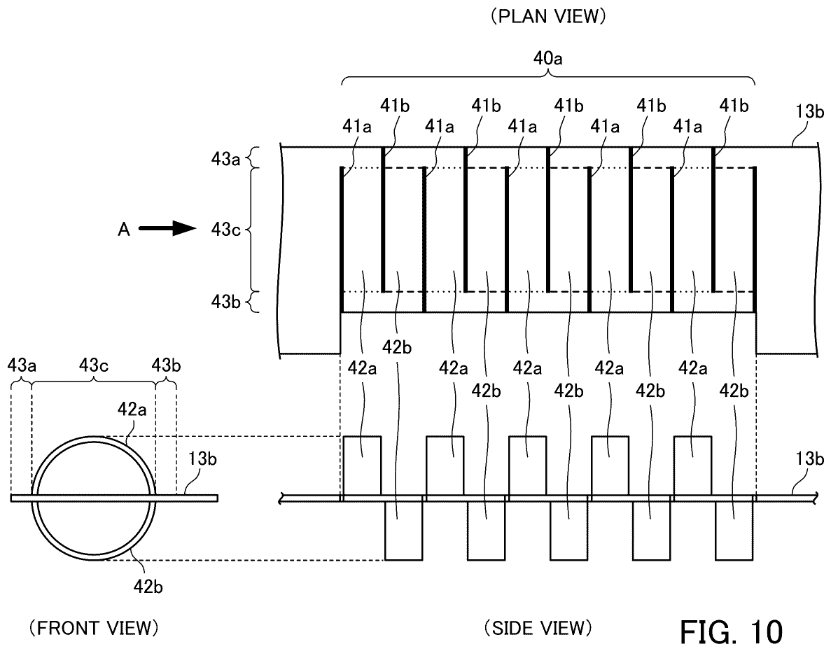

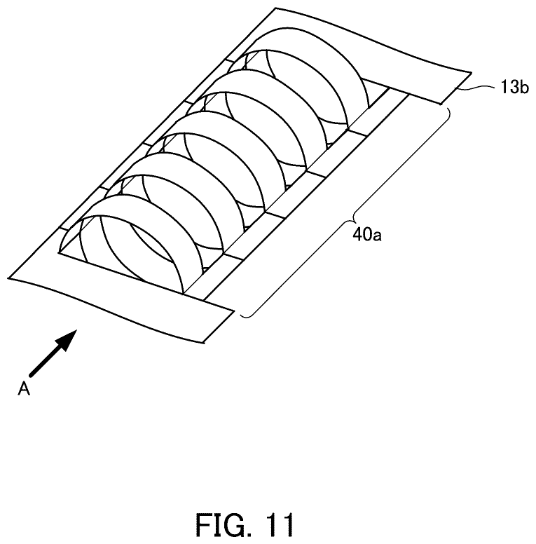

In this connection, the above-described embodiment forms the coil portion 40 that is rectangular (rhombus) in cross section. Alternatively, the coil portion 40 may have a cross-sectional shape of any other polygon such as a hexagon. Here, the coil portion 40 may desirably have a cross-sectional shape of a circle, as illustrated in FIGS. 10 and 11.

FIG. 10 includes a plan view, front view, and side view illustrating a modification example of the coil portion. FIG. 11 is a perspective view illustrating the modification example of the coil portion. In this connection, the same reference numerals as used in FIGS. 3 and 4 are given to corresponding components illustrated in FIGS. 10 and 11.

In the example modification of FIGS. 10 and 11, the coil portion 40 in the above-described embodiment is modified to be a coil portion 40a. The coil portion 40a differs from the coil portion 40 in that the coil portion 40a is circular in cross section. That is, in the coil portion 40a, each inter-slit region 42a is curved upward with respect to the principal surface of the lead frame 13b to form a semicircle projecting upward. In addition, each inter-slit region 42b is curved downward with respect to the principal surface of the lead frame 13b to form a semicircle projecting downward. With the inter-slit regions 42a and 42b having such curved shapes, the coil portion 40a is circular in cross section.

In this connection, the side regions 43a and 43b of the inter-slit regions 42a and 42b are kept on the same plane as the principal surface of the lead frame 13b, as in the coil portion 40. The side regions 43a and 43b connect adjacent inter-slit regions. Therefore, the coil portion 40a has a spiral-shaped coil.

The length L1 of the coil portion 40a, the length L2 of one turn of the coil, the width L3 of the coil, the width W of the lead frame 13b, the diameter D of the coil, and the number of turns n of the coil are the same as those used in the above-described coil portion 40. The spiral-shaped coil has a larger cross-sectional area than the coil portion 40, which increases the inductance. This results in reducing an inrush current caused by a high-frequency surge reliably and thus reducing the possibility of damage to the control IC 32.

In this connection, the manufacturing method described with reference to FIGS. 5 and 6 may also be employed to form the coil portion 40a. In the case of forming the coil portion 40a, the cross-sectional shape of each projection included in the die 52a illustrated in FIG. 6 when viewed from the front (when viewed in the direction of arrow A) is a semicircle facing up, and the cross-sectional shape of each projection included in the die 52b is a semicircle facing down.

The disclosed technique makes it possible to reduce an inrush current caused by a surge and thus reduce the possibility of damage to electronic components inside a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an electronic component; and
an external connection wiring part formed of a wiring member that is of a plate shape and has two ends opposite to each other, a direction from one end to the other end thereof being a first direction, the one end thereof being connected to the electronic component, the wiring member including:
a coil portion extending in the first direction, and
two plate portions that are flat, respectively provided closer to the one end than is the coil portion and closer to the other end than is the coil portion, wherein
in a top view of the wiring member, the wiring member has a first side and a second side opposite to each other, a direction from the first side to the second side being a second direction that is orthogonal to the first direction; and
the coil portion includes:
a plurality of first slits extending from the first side of the wiring member in the second direction,
a plurality of second slits extending from the second side of the wiring member in a direction that is opposite to the second direction and orthogonal to the first direction, the plurality of first slits and the plurality of second slits being arranged alternately,
a plurality of first inter-slit regions, each between one of the first slits and one of the second slits adjacent thereto in the first direction, and having a first peak portion at a center portion thereof, and
a plurality of second inter-slit regions, each between one of the second slits and one of the first slits adjacent thereto in the first direction, and having a second peak portion at a center portion thereof, the plurality of first peak portions and the plurality of second peak portions being on opposite sides of a principal surface of the wiring member.

2. The semiconductor device according to claim 1, further comprising a semiconductor chip configured to perform a switching operation, wherein
the electronic component includes a control circuit that controls the switching operation of the semiconductor chip.

3. The semiconductor device according to claim 1, wherein the other end of the wiring member is an output terminal configured to output a voltage representing a measurement value of a temperature of the electronic component.

4. The semiconductor device according to claim 1, wherein
each of the first inter-slit regions is bent at the first peak portion thereof, and
each of the second inter-slit regions is bent at the second peak portion thereof.

5. The semiconductor device according to claim 1, wherein
the plurality of first inter-slit regions and the plurality of second inter-slit regions are respectively curved in two directions opposite to each other.

6. The semiconductor device according to claim 1, further comprising:
a case housing the electronic component and the coil portion of the wiring member, the one end of the wiring member being in the case, and the other end of the wiring member extending to outside of the case,
wherein the case includes:
a flat surface on which the coil portion and the plate portions are arranged, and
a recess accommodating the plurality of first inter-slit regions or the plurality of second inter-slit regions of the coil portion projecting thereinto.

7. A manufacturing method, comprising:
forming, in a plate-shaped wiring member, a plurality of first slits and a plurality of second slits arranged alternately in a first direction, to thereby form a plurality of first inter-slit regions and a plurality of second inter-slit regions in the wiring member, wherein
in a top view of the wiring member, the wiring member has a first side and a second side opposite to each other, a direction from the first side to the second side being a second direction that is orthogonal to the first direction,
the plurality of first slits extend from the first side of the wiring member in the second direction,
the plurality of second slits extend from the second side of the wiring member in a direction that is opposite to the second direction and is orthogonal to the first direction,
each of the plurality of first inter-slit regions is a region between one of the first slits and one of the second slits adjacent thereto in the first direction, and
each of the plurality of second inter-slit regions is a region between one of the second slits and one of the first slits adjacent thereto in the first direction; and
forming a coil portion by
projecting a center portion of each of the plurality of first inter-slit regions in a third direction orthogonal to a principal surface of the wiring member, and
projecting a center portion of each of the plurality of second inter-slit regions in a direction opposite to the third direction.

8. The manufacturing method according to claim 7, wherein the forming of the coil portion includes:
bending said each first inter-slit region such that the center portion of said each first inter-slit region projects in the third direction, and
bending said each second inter-slit region such that the center portion of said each second inter-slit region projects in the direction opposite to the third direction.

9. The manufacturing method according to claim 7, wherein the forming of the coil portion includes:
curving said each first inter-slit region in the third direction, and
curving said each second inter-slit region in the direction opposite to the third direction.
